(19) United States
(12) Patent Application Publication
(10) Pub. No.: US 2025/0189641 A1
(43) Pub. Date: Jun. 12, 2025

(54) SIMULATION METHOD AND MULTIPATH INTERFERENCE CORRECTION SYSTEM AND METHOD FOR COAXIAL SCANNING LIDAR

(71) Applicant: KOREA ADVANCED INSTITUTE OF SCIENCE AND TECHNOLOGY, Daejeon (KR)

(72) Inventors: Yong-Hwa PARK, Daejeon (KR); Sunghyun LEE, Daejeon (KR); Yoonseop LIM, Daejeon (KR)

(21) Appl. No.: 18/978,149

(22) Filed: Dec. 12, 2024

(30) Foreign Application Priority Data
Dec. 12, 2023 (KR) 10-2023-0179814

(51) Int. Cl. G01S 7/4915; G01S 17/36; G01S 17/894; G06N 20/00

(52) U.S. Cl. CPC G01S 7/4915; G01S 17/36; G01S 17/894; G06N 20/00

(57) ABSTRACT

According to one embodiment of the present disclosure, a multipath interference correction system for a coaxial scanning LIDAR, includes a scanner driving unit configured to drive a scanner included in a coaxial scanning LIDAR and obtain a position signal of the scanner, a measurement light modulation signal input unit configured to obtain a demodulation signal of measurement light emitted from laser of the coaxial scanning LIDAR, a detection light input unit configured to receive detection light mixed with reflection light and multiple interference light from an avalanche photodiode of the coaxial scanning LIDAR and output a detection light signal, and a real-time processor for outputting a depth map based on the detection light signal, the demodulation signal of the measurement light, and the position signal of the scanner.

### CROSS-REFERENCE TO RELATED APPLICATION

This application claims the benefit of and priority to Korean Patent Application No. 10-2023-0179814, filed on Dec. 12, 2023, the entire disclosure(s) of which is hereby incorporated herein by reference in its entirety.

### TECHNICAL FIELD

The present disclosure relates to a simulation method and a multipath interference correction system and method for coaxial scanning LIDAR, and more particularly, to a method for simulating an amplitude-modulated continuous wave (AMCW) coaxial scanning light detection and ranging (LIDAR), and a system and method for correcting multipath interference by multiple light reflections in a depth map using the same.

### BACKGROUND

LIDAR is a device that uses lasers to detect the surrounding environment and measure distances, and is applied to autonomous vehicles, robots, drones, or the like, and is contributing to improving three-dimensional recognition performance.

There are two methods for measuring a distance to an object using LIDAR, that is, there are a direct time-of-flight (TOF) measurement method and an indirect TOF measurement method.

The direct time-of-flight measurement method is a technology that measures the time it takes for a laser beam to travel to an object and return after being emitted, and directly measures the travel time of the emitted light using a high-precision time-to-digital converter. An amplitude-modulated continuous wave (AMCW) TOF measurement method, one of the indirect TOF measurement methods, is a technology that modulates the amplitude of a continuous wave and transmits the modulated wave, and measures the distance by estimating phase lag of the light reflected from an object. AMCW indirect TOF LIDAR is widely used in relatively short ranges (for example, up to 10 m) due to high measurement accuracy and relatively low cost compared to direct TOF LIDAR.

A LIDAR system measures the distance to an object based on the signal that is input to the LIDAR system when the emitted laser light is reflected from the object. In other words, in order for a LIDAR system to accurately measure the distance to an object, only the signal reflected from the object should be input to the LIDAR system. However, when measuring an object placed in front of an inwardly angled background, such as the corner of a building, the emitted laser or the light reflected from the object may be reflected again (multiple reflections), so not only the light reflected from the object but also the light (multiple interference light) reflected from other locations in the vicinity may be received by the LIDAR system. This phenomenon is called multipath interference (MPI). The multiple interference light has a different phase and amplitude from the light reflected from the object, and when the LIDAR system measures the distance to an object based on light that is a mixture of light reflected from the object and multiple interference light, errors in the distance measurement occur.

Many attempts have been made to correct distance measurement errors caused by the multipath interference, but there is a problem that the correction takes a lot of time, making real-time application difficult, and that multipath interference cannot be completely removed.

### SUMMARY

An object of the present disclosure is to provide a simulation method of a coaxial scanning LIDAR that simulates various mixed light by modeling and combining a reflection light path and a multiple interference light path directly reflected from an object for the measurement light transmitted from the coaxial scanning LIDAR.

Another object of the present disclosure is to provide a multipath interference correction system and method for a coaxial scanning LIDAR, which trains to remove multi interference light from mixed light simulated by a simulation method of a coaxial scanning LIDAR, thereby removing multi interference light from the detection light of the coaxial scanning LIDAR and correcting a depth map derived from the detection light.

The present disclosure may be implemented in various ways, including a device (system), a method, a computer program stored in a computer-readable medium, or a computer-readable medium having a computer program stored therein.

According to one embodiment of the present disclosure, there is provided a simulation method for a coaxial scanning LIDAR, including a laser that transmits measurement light, a two-axis scanner that scans an object by rotating the measurement light about a coaxial axis, and an avalanche photodiode that detects a mixed light in which reflection light directly reflected from the object and multiple interference light are mixed, the simulation method including: a step of modeling a detection light signal to which measurement light modulation, a reflection light model, and a multiple interference light model are applied; a step of modeling a physical response of the avalanche photodiode; a modeling step of generating four phase-shifted measurement light modulation signals for the measurement light; and a modeling step of obtaining cross-correlation between the detection light signal and the four phase-shifted measurement light modulation signals.

Preferably, the step of modeling the detection light signal to which the measurement light modulation, the reflection light model, and the multiple interference light model are applied includes a step of modeling a reflection light signal based on the reflection light model, modeling a multiple interference light signal based on the multiple interference light model, deriving the number of photons of the detection light based on power and carrier travel time of the detection light signal, energy of a photon, and a laser wavelength, and determining the number of photons of the detection light by applying background light and photon shot noise.

Preferably, the step of modeling a physical response of the avalanche photodiode includes a step of removing an influence of dark current, TIA noise, and thermal noise from a detection light signal received by the coaxial scanning LIDAR.

Preferably, the modeling step of generating four phase-shifted measurement light modulation signals for the measurement light includes a step of removing noise by multiplexing a demodulation signal of the measurement light into four phase shifts.

Preferably, the modeling step of obtaining the cross-correlation between the detection light signal and the four phase-shifted measurement light modulation signals includes a step of obtaining a measurement light modulation signal phase-shifted by 0 degrees, a measurement light modulation signal phase-shifted by 90 degrees, a measurement light modulation signal phase-shifted by 180 degrees, and a measurement light modulation signal phase-shifted by 270 degrees for the detection light signal, performing a one-dimensional numerical integration of each of the measurement light modulation signals, and multiplying each component subjected to the one-dimensional numerical integration by a reciprocal of an integration time (T_int) to obtain the cross-correlation in each phase.

According to one embodiment of the present disclosure, there is provided a multipath interference correction system for a coaxial scanning LIDAR, the multiple interface correction system comprising: a scanner driving unit configured to drive a scanner included in a coaxial scanning LIDAR and obtain a position signal of the scanner; a measurement light modulation signal input unit configured to obtain a demodulation signal of measurement light emitted from laser of the coaxial scanning LIDAR; a detection light input unit configured to receive detection light mixed with reflection light and multiple interference light from an avalanche photodiode of the coaxial scanning LIDAR and output a detection light signal; and a real-time processor for outputting a depth map based on the detection light signal, the demodulation signal of the measurement light, and the position signal of the scanner, in which the real-time processor includes a depth map generation unit configured to generate a depth map based on the detection light based on the detection light signal, the demodulation signal of the measurement light, and the scanner position signal, and trained extreme gradient boosting (XG Boost) configured to be trained to correct distortion caused by the multiple interference light in the depth map based on the detection light and output the depth map in which multipath interference is corrected.

Preferably, the trained XG boost is trained to correct a depth map error due to multiple interference light by using an XG Boost regressor based on a mixed light data set simulated by the simulation method of the coaxial scanning LIDAR.

Preferably, the X-Boost regressor determines an optimized hyperparameter using a Tree-structured Parzen Estimator (TPE)-based Bayesian optimization algorithm.

Preferably, the simulation method of the coaxial scanning LIDAR includes a step of modeling a detection light signal to which measurement light modulation, a reflection light model, and a multiple interference light model are applied, a step of modeling a physical response of the avalanche photodiode, a modeling step of generating four phase-shifted measurement light modulation signals for the measurement light, and a modeling step of obtaining cross-correlation between the detection light signal and the four phase-shifted measurement light modulation signals.

Preferably, the step of modeling the detection light signal to which the measurement light modulation, the reflection light model, and the multiple interference light model are applied includes a step of modeling a reflection light signal based on the reflection light model, modeling a multiple interference light signal based on the multiple interference light model, deriving the number of photons of the detection light based on power and carrier travel time of the detection light signal, energy of a photon, and a laser wavelength, and determining the number of photons of the detection light by applying background light and photon shot noise.

Preferably, the step of modeling a physical response of the avalanche photodiode includes a step of removing an influence of dark current, TIA noise, and thermal noise from a detection light signal received by the coaxial scanning LIDAR.

Preferably, the modeling step of generating four phase-shifted measurement light modulation signals for the measurement light includes a step of removing noise by multiplexing a demodulation signal of the measurement light into four phase shifts.

Preferably, the modeling step of obtaining the cross-correlation between the detection light signal and the four phase-shifted measurement light modulation signals includes the step of obtaining a measurement light modulation signal phase-shifted by 0 degrees, a measurement light modulation signal phase-shifted by 90 degrees, a measurement light modulation signal phase-shifted by 180 degrees, and a measurement light modulation signal phase-shifted by 270 degrees for the detection light signal, performing a one-dimensional numerical integration of each of the measurement light modulation signals, and multiplying each component subjected to the one-dimensional numerical integration by a reciprocal of an integration time (T_int) to obtain the cross-correlation in each phase.

According to one embodiment of the present disclosure, there is provided a multipath interference correct method for a coaxial scanning LIDAR including a scanner driving unit configured to drive a scanner included in a coaxial scanning LIDAR and obtain a position signal of the scanner, a measurement light modulation signal input unit configured to obtain a demodulation signal of measurement light emitted from laser of the coaxial scanning LIDAR, a detection light input unit configured to receive detection light mixed with reflection light and multiple interference light from an avalanche photodiode of the coaxial scanning LIDAR and output a detection light signal, and a real-time processor for outputting a depth map based on the detection light signal, the demodulation signal of the measurement light, and the position signal of the scanner, the multipath interference correct method including: a depth map generation step of generating, by the real-time processor, a depth map based on the detection light based on the detection light signal, the demodulation signal of the measurement light, and the scanner position signal, and a step of outputting the depth map in which the multipath interference is corrected using trained extreme gradient boosting (XG Boost) trained to correct distortion caused by the multiple interference light in the depth map based on the detection light.

Preferably, the trained XG boost is trained to correct a depth map error due to multiple interference light by using an XG Boost regressor based on a mixed light data set simulated by the simulation method of the coaxial scanning LIDAR.

Preferably, the X-Boost regressor determines an optimized hyperparameter using a Tree-structured Parzen Estimator (TPE)-based Bayesian optimization algorithm.

Preferably, the simulation method of the coaxial scanning LIDAR includes a step of modeling a detection light signal to which measurement light modulation, a reflection light model, and a multiple interference light model are applied, a step of modeling a physical response of the avalanche photodiode, a modeling step of generating four phase-shifted measurement light modulation signals for the measurement light, and a modeling step of obtaining cross-correlation between the detection light signal and the four phase-shifted measurement light modulation signals.

Preferably, the step of modeling the detection light signal to which the measurement light modulation, the reflection light model, and the multiple interference light model are applied includes a step of modeling a reflection light signal based on the reflection light model, modeling a multiple interference light signal based on the multiple interference light model, deriving the number of photons of the detection light based on power and carrier travel time of the detection light signal, energy of a photon, and a laser wavelength, and determining the number of photons of the detection light by applying background light and photon shot noise.

Preferably, the step of modeling a physical response of the avalanche photodiode includes a step of removing an influence of dark current, TIA noise, and thermal noise from a detection light signal received by the coaxial scanning LIDAR.

Preferably, the modeling step of generating four phase-shifted measurement light modulation signals for the measurement light includes a step of removing noise by multiplexing a demodulation signal of the measurement light into four phase shifts.

Preferably, the modeling step of obtaining the cross-correlation between the detection light signal and the four phase-shifted measurement light modulation signals includes the step of obtaining a measurement light modulation signal phase-shifted by 0 degrees, a measurement light modulation signal phase-shifted by 90 degrees, a measurement light modulation signal phase-shifted by 180 degrees, and a measurement light modulation signal phase-shifted by 270 degrees for the detection light signal, performing a one-dimensional numerical integration of each of the measurement light modulation signals, and multiplying each component subjected to the one-dimensional numerical integration by a reciprocal of an integration time (T_int) to obtain the cross-correlation in each phase.

### Advantageous Effects

According to the present disclosure, it is possible to simulate various mixed light by modeling and combining the reflection light path and the multiple interference light path directly reflected from the object for the measurement light transmitted from the coaxial scanning LIDAR.

According to the present disclosure, it is possible to accurately estimate and remove the multiple interference light from detection light detected by an indirect TOF-based coaxial scanning LIDAR, thereby extracting the reflection light directly reflected from the object.

According to the present disclosure, it is possible to generate a simulation model by combining a multiple interference optical path model and a noise characteristic model by applying parallel phase demodulation, and it is possible to correct multipath interference in real time by training data generated through the simulation model using Bayesian optimized XG Boost.

The effects of the present disclosure are not limited to the effects mentioned above, and other effects not mentioned can be clearly understood by a person having ordinary knowledge in the technical field to which the present disclosure belongs (“ordinary skilled in the art”) from the description of the claims.

### BRIEF DESCRIPTION OF THE DRAWINGS

Embodiments of the present disclosure will be described below with reference to the accompanying drawings, in which like reference numerals represent similar elements, but are not limited thereto.

FIG. 1 is a diagram illustrating an optical system of a coaxial scanning LIDAR according to the present disclosure, and is a diagram for explaining a principle by which multipath interference occurs.

FIG. 2 is a diagram illustrating an operation flow of a simulation method of a parallel phase modulation-based AMCW coaxial scanning LIDAR according to the present disclosure.

FIG. 3 is a diagram illustrating in detail steps for obtaining cross-correlation between a signal-processed detection light signal and four phase-shifted measurement light modulation signals in a simulation of an AMCW coaxial scanning LIDAR of FIG. 2.

FIG. 4 is a diagram illustrating a multipath interference correction system for a coaxial scanning LIDAR according to the present disclosure.

### DETAILED DESCRIPTION

Hereinafter, specific details for implementing the present disclosure will be described in detail with reference to the attached drawings. However, in the following description, specific descriptions of widely known functions or configurations will be omitted when there is a risk of unnecessarily obscuring the gist of the present disclosure.

In the attached drawings, identical or corresponding components are given the same reference numerals. In addition, in the description of the embodiments below, the description of identical or corresponding components may be omitted. However, even when the description of a component is omitted, it is not intended that such a component is not included in any embodiment.

The advantages and features of the embodiments disclosed in this specification, and the methods for achieving them, will become clear with reference to the embodiments described below together with the accompanying drawings. However, the present disclosure is not limited to the embodiments disclosed below, but can be implemented in various different forms, and these embodiments are only provided to fully inform a person skilled in the art related to the present disclosure of the scope of the disclosure.

Unless otherwise defined, all terms (including technical and scientific terms) used in this specification may be used with a meaning that can be commonly understood by a person of ordinary skill in the art to which the present disclosure belongs. In addition, terms defined in commonly used dictionaries shall not be ideally or excessively interpreted unless explicitly specifically defined.

For example, the term “technology” may refer to systems, methods, computer-readable instructions, modules, algorithms, hardware logic, and/or operations as permitted by the context described above and throughout the document.

Hereinafter, terms used in this specification will be briefly explained, and the disclosed embodiments will be specifically described. The terms used in this specification have been selected from widely used general terms as much as possible while considering the functions in the present disclosure, but this may vary depending on the intention of engineers engaged in the relevant field, precedents, or the emergence of new technologies. In addition, in certain cases, there are terms arbitrarily selected by the applicant, and in this case, the meanings thereof will be described in detail in the description of the relevant disclosure. Therefore, the terms used in the present disclosure should be defined based on the meanings of the terms and the overall contents of the present disclosure, rather than simply the names of the terms.

In this specification, singular expressions include plural expressions unless the context clearly specifies that they are singular. In addition, plural expressions include singular expressions unless the context clearly specifies that they are plural. When it is said that a part includes a certain component throughout the specification, this does not exclude other components unless specifically stated to the contrary, but rather means that other components may be included.

In the present disclosure, the terms “comprising” “including” and the like may indicate the presence of features, steps, operations, elements, and/or components, but such terms do not exclude the addition of one or more other functions, steps, operations, elements, components, and/or combinations thereof.

In the present disclosure, when a specific component is referred to as being “coupled,” “combined,” “connected,” “associated,” or “reacting” with any other component, the specific component may be directly coupled, combined, connected, and/or associated with, or reacting with, the other component, but is not limited thereto. For example, one or more intermediate components may exist between the specific component and the other component. Furthermore, “and/or” in the present disclosure may include each of one or more of the listed items or a combination of at least a portion of one or more of the listed items.

In the present disclosure, terms such as “first”, “second”, and the like are used to distinguish specific components from other components, and the components described above are not limited by these terms. For example, a “first” component may be used to refer to an element having the same or similar form as a “second” component.

In the present disclosure, the measurement light is a light beam transmitted from laser of a coaxial scanning LIDAR, and may be an amplitude-modulated continuous wave (AMCW). In the present disclosure, the reflection light may be a light beam that is directly reflected from an object by the measurement light transmitted from the coaxial scanning LIDAR and inputted into the coaxial scanning LIDAR. In the present disclosure, the multiple interference light may be a light beam that is reflected from the surroundings or reflected again to the object from the surroundings and inputted into the coaxial scanning LIDAR to cause interference in the reflection light, in addition to the direct reflection from the object. In the present disclosure, the detection light may be a light beam detected by an avalanche photodiode, and may be a light beam that is a mixture of reflection light and multiple interference light. In the present disclosure, the measurement light signal may be a signal that converts the measurement light into an electrical signal. In the present disclosure, the multiple interference light signal may be a signal that converts multiple interference light into an electrical signal. In the present disclosure, the reflection light signal may be a signal that converts reflection light into an electrical signal. In the present disclosure, the detection light signal may be a signal that converts detection light into an electrical signal.

Unless otherwise stated, the LIDAR in the present disclosure may be a coaxial scanning LIDAR. The coaxial scanning LIDAR may be one of typical three-dimensional depth measurement devices that scan the environment and measures the distance by rotating a laser beam about a coaxial axis. The coaxial scanning LIDAR may transmit an amplitude-modulated continuous wave (AMCW) and measure phase lag of the AMCW reflection light directly reflected from the object to calculate the distance to the object.

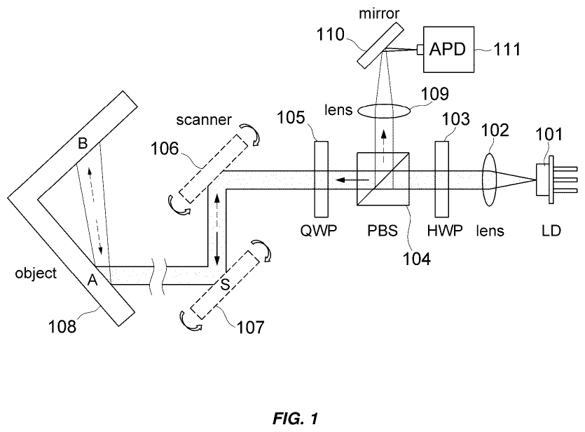

FIG. 1 is a diagram illustrating an optical system of a coaxial scanning LIDAR according to the present disclosure, and is a diagram for explaining a principle by which multipath interference occurs.

The coaxial scanning LIDAR includes a laser 101 that transmits measurement light, a lens 102 that expands the measurement light transmitted from the laser 101, a half-wave plate (HWP) 103 that changes the amplitude of the measurement light expanded by the lens 102, a polarizing beam splitter (PBS) (104) that orthogonally separates measurement light that is transmitted from the laser 101 and has passed through the half-wave plate 103 and reflection light reflected from an object 108, a quarter-wave plate (QWP) 105 that changes the amplitude and phase of the measurement light that is transmitted from the laser 101 and has passed through the lens 102, the half-wave plate 103, and the polarizing splitter 104, two-axis scanners 106 and 107 that scan the object 108 by rotating the measurement light whose amplitude and phase are changed by the quarter-wave plate 14 about the coaxial axis, a lens 109 that collects mixed light in which reflection light directly reflected from the object 108 and multiple interference light are mixed, a mirror 110 that changes the path of the mixed light, and an avalanche photodiode 111 that detects mixed light whose path is changed by the mirror 110. The mixed light detected by the avalanche photodiode 111 is detection light, and the avalanche photodiode 111 outputs a detection light signal.

The measurement light emitted from the laser 101 is expanded by the lens 102 and the amplitude of the emitted measurement light is changed by the half-wave plate 103. Moreover, the measurement light passes through the polarization splitter 104, the amplitude and phase of the measurement light are changed by the quarter-wave plate 105, and the measurement light is transmitted to the object 108 while being rotated 360 degrees by the two-axis scanners 106 and 107.

The measurement light may be directly reflected (reflection light) from a reflection point A of the object 108, or the light reflected from the object 108 may be re-reflected (multiple interference light) by another point B and mixed with the reflection light. That is, the mixed light of the reflection light and the multiple interference light may be input to the LIDAR through the object 108. The mixed light of the reflection light and the multiple interference light is incident on the quarter-wave plate 105 through the two-axis scanners 106 and 107, separated from the measurement light by the polarization splitter 104, and incident on the lens 109 positioned in the orthogonal direction. The lens 109 collects the mixed light, and the mirror 110 changes the path of the mixed light to the avalanche photodiode 111. Moreover, the avalanche photodiode 111 detects the mixed light and outputs a detection light signal.

That is, the avalanche photodiode 111 detects detection light that is a mixture of reflection light and multiple interference light, not reflection light directly reflected from the object, and since the LIDAR derives the depth map of the object based on the detection light, not the reflection light, a measurement error occurs in the depth map of the object.

The present disclosure may be applied to an AMCW coaxial scanning LIDAR. As illustrated in FIG. 1, in the AMCW coaxial scanning LIDAR, the measurement light is focused and reflected at the reflection point A of the object, and this reflection point is very narrow, usually on the scale of mm. Another point B that is re-reflected from the reflection point A and generates the multiple interference light may also be considered narrow, and when looking at the power distribution, in the case of a Gaussian beam, most of the multiple interference light is distributed at the center of B.

The cross-correlation between the reflection light and the multiple interference light may be expressed in an expression as illustrated in Expression 1.

$${C}_{net} ( w ) = {Γ}_{D} {e}^{j {ϕ}_{D} ( w )} + {Γ}_{M} {e}^{j {ϕ}_{M} ( w )} \qquad [ Expression 1 ]$$

Here, Γ_{D} is the amplitude of the cross-correlation including the reflection light, and Pp is the phase lag of the cross-correlation including the reflection light. Γ_{M} is an amplitude of the cross-correlation including the multiple coherence light, and ϕ_{M} is a phase lag of the cross-correlation including the multiple coherence light.

The amplitude and phase lag of each cross-correlation may be modeled based on the radiometric properties as illustrated in Expressions 2 to 5 below.

$${Γ}_{D} = {Γ}_{R} \frac{{ρ}_{SAS}}{{‖ {d}_{AS} ‖}^{2}} \qquad [ Expression 2 ]$$

$${Γ}_{M} = {Γ}_{R} \frac{( {ρ}_{S A B} {ρ}_{A B A} {ρ}_{B A S} )}{{‖ {d}_{A S} ‖}^{2}} \qquad [ Expression 3 ]$$

$${ϕ}_{D} ( w ) = \frac{4 π f {d}_{A S}}{c} \qquad [ Expression 4 ]$$

$${ϕ}_{M} ( w ) = \frac{4 π f ( {d}_{A S} + {d}_{A B} )}{c} \qquad [ Expression 5 ]$$

Here, Γ_{R} is an initial value of the cross-correlation. d_{XY} is an absolute distance from a center of X to a center of Y, d_{AS} is an absolute distance from a center of a point S in FIG. 1 to a center of a point A, and d_{AB} is an absolute distance from the center of the point A to a center of a point B in FIG. 1.

ρ_{XYZ} is a bidirectional reflectance distribution function in a direction from X through Y to Z, ρ_{SAS} is a bidirectional reflectance distribution function between the point S, point A, and point S in FIG. 1, ρ_{SAB} is a bidirectional reflectance distribution function between the point S, point A, and point B in FIG. 1, ρ_{ABA} is a bidirectional reflectance distribution function between the point A, point B, and point A in FIG. 1, and PBAS is a bidirectional reflectance distribution function between the point B, point A, and point S in FIG. 1.

The amplitude equations of the cross-correlation in Expressions 2 and 3 may be derived based on the fact that the intensity of the received light is proportional to the reflectivity and inversely proportional to the square of the travel length of the light beam. The mixed light including the directly reflected reflection light and the multi-interfered light may be modeled based on Expressions 2 to 5.

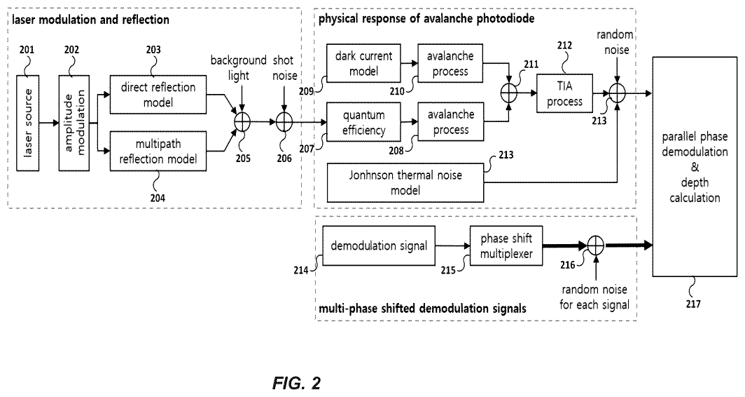

FIG. 2 is a diagram illustrating an operation flow of a simulation method of a parallel phase modulation-based AMCW coaxial scanning LIDAR according to the present disclosure.

This simulation method may include a step of modeling a detection light signal to which measurement light modulation, a reflection light model, and a multiple interference light model are applied, a step of modeling a physical response of the avalanche photodiode, a modeling step of generating four phase-shifted measurement light modulation signals, and a modeling step of obtaining cross-correlation between the signal processed detection light signal and four phase-shifted measurement light modulation signals.

The step of modeling the detection light signal to which the measurement light modulation, the reflection light model, and the multiple interference light model are applied will be described. A light beam emitted from a laser source 201 is amplitude-modulated 202 and then scanned on an object, and reflection light and multiple interference light may be mixed and received from the object. The reflection light may be modeled with a reflection light model 203 based on Expressions 2 and 4, and the multiple interference light may be modeled with a multiple interference light model 204 based on Expressions 3 and 5. The number of photons of the mixed light of the received reflection light and multiple interference light may be derived from the power and the carrier travel time of the received detection light, the energy of the photon, and the wavelength of the laser. However, the number of photons actually received by the LIDAR should consider background light 205, and may be probabilistically determined by a photon shot noise 206.

The step of modeling the physical response of the avalanche photodiode is described. A photon received by a LIDAR may be converted 207 into an electron in an avalanche photodiode and amplified through an avalanche process 208. Meanwhile, as another type of electrical signal, there is a dark current, which is an electrical noise mainly affected by the temperature of an avalanche photodiode, and an electron derived through dark current modeling 209 may be amplified in an avalanche process 210. An electrical signal based on a LIDAR-received photon and an electrical signal based on a dark current are combined 211 to remove the influence of the dark current. In addition, a sensor simulation model of an AMCW coaxial scanning LIDAR may be generated, in which TIA noise 212 generated in a transimpedance amplifier (TIA) process, thermal noise 213 generated due to a load of a circuit, and other random noises are removed 214.

The modeling steps of generating the four phase-shifted measurement light modulation signals are described. The demodulated signal 214 of the measurement light is multiplexed 215 with four phase shifts to remove noise 216, and the cross-correlation is calculated in parallel, and based on this, the composite depth and the total amplitude and phase of the cross-correlation are calculated 217.

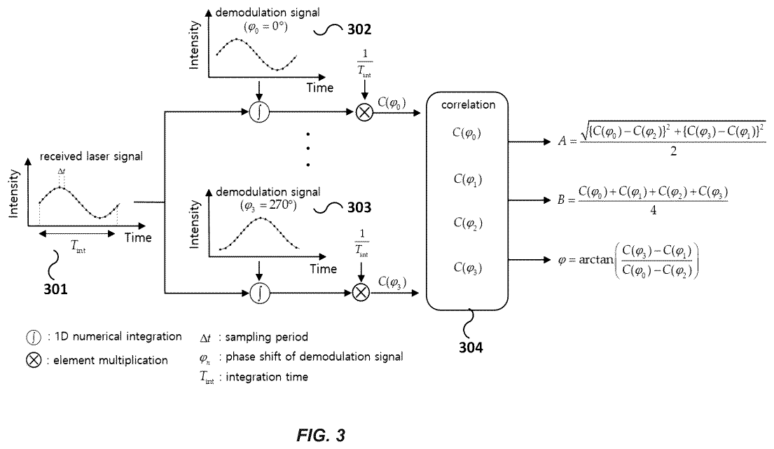

The modeling step for obtaining the cross-correlation between the signal-processed detection light signal and four phase-shifted measurement light modulation signals is described. FIG. 3 is a diagram illustrating in detail the step 217 for obtaining the cross-correlation between a signal-processed detection light signal and four phase-shifted measurement light modulation signals in the simulation of the AMCW coaxial scanning LIDAR of FIG. 2.

By performing a one-dimensional numerical integration on a measurement light modulation signal phase-shifted by 0 degrees, a measurement light modulation signal phase-shifted by 90 degrees, a measurement light modulation signal phase-shifted by 180 degrees, and a measurement light modulation signal phase-shifted by 270 degrees for the received detection light signal 301 in FIG. 3 and multiplying each component subjected to the one-dimensional numerical integration by a reciprocal of an integration time (T_int), the cross-correlation (C(ϕ₀), C(ϕ₁), C(ϕ₂), C(ϕ₃)) 304 in each phase is obtained.

The amplitude A and phase ϕ of the detection light derived from the cross-correlation at each phase are expressed in Expressions 8 and 9 below.

$$A = \frac{\sqrt{{( C ( {ϕ}_{0} ) - C ( {ϕ}_{2} ) )}^{2} + {( C ( {ϕ}_{3} ) - C ( {ϕ}_{1} ) )}^{2}}}{2} \qquad [ Expression 8 ]$$

$$ϕ = arctan ( \frac{C ( {ϕ}_{3} ) - C ( {ϕ}_{1} )}{C ( {ϕ}_{0} ) - C ( {ϕ}_{2} )} ) \qquad [ Expression 9 ]$$

Based on the simulation of the parallel phase modulation-based AMCW coaxial scanning LIDAR of FIG. 2, a plurality of mixed light data sets are constructed at the simulation level.

Based on the plurality of mixed light data sets constructed in this way, an XG Boost ensemble is trained.

Extreme gradient boosting (XG Boost) is the same as a gradient boosting method that trains residuals using multiple weak learners, and is improved in terms of overfitting, learning speed, and accuracy. Compared with the existing gradient boosting method, the XG Boost uses a regularization term in the loss function to prevent overfitting, and trains classification and regression trees (CART) in parallel to accelerate the learning process. In addition, mathematical accuracy is improved by adding a second-order Taylor expansion to the loss function. In addition, the XG Boost uses prefetching considering cache to improve the data interface, which can reduce the learning time.

In the present disclosure, a model is constructed to correct errors due to the multiple interference light in the AMCW coaxial scanning LIDAR by training multiple interference light using an XG Boost regressor.

In order to accurately train the XG Boost regressor, optimized hyperparameters are determined using a Bayesian optimization algorithm based on Tree-structured Parzen Estimator (TPE). In this case, the optimized hyperparameters may be determined using a sequential model-based optimization (SMBO) algorithm.

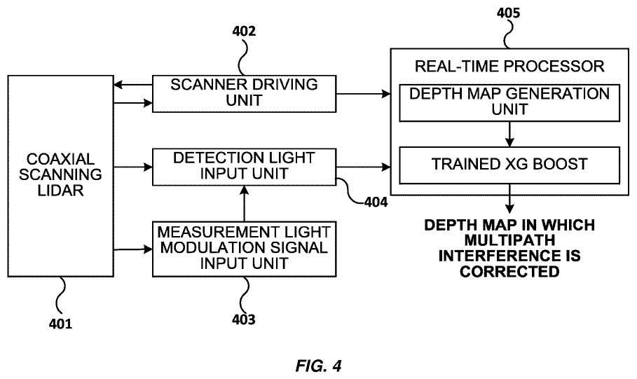

FIG. 4 is a diagram illustrating a multipath interference correction system of the coaxial scanning LIDAR according to the present disclosure.

The multipath interference correction system includes a scanner driving unit 402 which drives a scanner included in a coaxial scanning LIDAR 401 and obtains a position signal of the scanner, a measurement light modulation signal input unit to which a demodulation signal of measurement light emitted from laser of the coaxial scanning LIDAR is input, a detection light input unit 404 that receives detection light mixed with reflection light and multiple interference light from an avalanche photodiode of the coaxial scanning LIDAR 401 and outputs a detection light signal, and a real-time processor 405 that outputs a depth map based on the detection light signal, the demodulation signal of the measurement light, and the position signal of the scanner. The real-time processor includes a depth map generation unit which generates a depth map based on the detection light based on the detection light signal, the demodulation signal of the measurement light, and the scanner position signal, and trained extreme gradient boosting (XG Boost) which is trained to correct distortion caused by the multiple interference light in the depth map based on the detection light and outputs the depth map in which multipath interference is corrected.

The trained XG Boost of the present disclosure may be a model trained to correct the depth map errors due to the multiple interference light by using an XG Boost regressor based on the simulated mixed-light data set through the simulation of FIG. 2. In addition, the XG Boost regressor may determine optimized hyperparameters by using a Bayesian optimization algorithm based on Tree-structured Parzen Estimator (TPE).

All of the methods and processes described above may be implemented and fully automated as software code modules executed by one or more general purpose computers or processors. The code modules may be stored on any type of computer readable storage medium or other computer storage device. Some or all of the methods may be implemented as specialized computer hardware.

Any routine description, element or block of a flowchart described herein and/or depicted in the accompanying drawings should be understood to potentially represent code, a module, a segment or a portion, which comprises one or more executable instructions for implementing a particular logical function or element. Alternative examples are included within the scope of the examples described herein, and elements or functions may be deleted or executed in the order from which they are illustrated or discussed, substantially synchronously or in reverse order, depending on the functionality understood herein.

Many variations and modifications can be made to the above-described embodiments, and it should be understood that the elements are just one of the permissible examples. All such modifications and variations are intended to be included within the scope of the present disclosure and protected by the following claims. The embodiments of the present disclosure described above may be implemented in the form of program instructions that can be executed by various computer components and recorded on a computer-readable recording medium. The computer-readable recording medium may include program instructions, data files, data structures, or the like, alone or in combination. The program instructions recorded on the computer-readable recording medium may be those specially designed and configured for the present disclosure or may be known and available to those skilled in the art of computer software. Examples of the computer-readable recording medium include magnetic media such as hard disks, floppy disks, and magnetic tapes, optical recording media such as CD-ROMs, DVDs, magneto-optical media such as floptical disks, and hardware devices specially configured to store and execute program instructions such as ROMs, RAMs, flash memories, and the like. Examples of program instructions include not only machine language codes such as those generated by a compiler, but also high-level language codes that can be executed by a computer using an interpreter, or the like. The hardware device may be configured to operate as one or more software modules to perform processing according to the present disclosure, and vice versa.

Although the present disclosure has been described above with specific details such as specific components and limited examples and drawings, these have been provided only to help a more general understanding of the present disclosure, and the present disclosure is not limited to the above examples, and those with common knowledge in the technical field to which the present disclosure belongs can make various modifications and variations from this description.

Therefore, the idea of the present disclosure should not be limited to the embodiments described above, and all modifications equivalent to or equivalent to the following claims as well as the claims are included in the scope of the idea of the present disclosure.

### DETAILED DESCRIPTION OF MAIN ELEMENTS

401: coaxial scanning LIDAR
402: scanner drive unit
403: measurement light modulation signal input unit
404: detection light input unit
405: real-time processor

What is claimed is:

1. A simulation method for a coaxial scanning LIDAR, including a laser that transmits measurement light, a two-axis scanner that scans an object by rotating the measurement light about a coaxial axis, and an avalanche photodiode that detects a mixed light in which reflection light directly reflected from the object and multiple interference light are mixed, the simulation method comprising:
a step of modeling a detection light signal to which measurement light modulation, a reflection light model, and a multiple interference light model are applied;
a step of modeling a physical response of the avalanche photodiode;
a modeling step of generating four phase-shifted measurement light modulation signals for the measurement light; and
a modeling step of obtaining cross-correlation between the detection light signal and the four phase-shifted measurement light modulation signals.

2. The simulation method of claim 1, wherein the step of modeling the detection light signal to which the measurement light modulation, the reflection light model, and the multiple interference light model are applied includes
a step of modeling a reflection light signal based on the reflection light model, modeling a multiple interference light signal based on the multiple interference light model, deriving the number of photons of the detection light based on power and carrier travel time of the detection light signal, energy of a photon, and a laser wavelength, and determining the number of photons of the detection light by applying background light and photon shot noise.

3. The simulation method of claim 1, wherein the step of modeling a physical response of the avalanche photodiode includes a step of removing an influence of dark current, TIA noise, and thermal noise from a detection light signal received by the coaxial scanning LIDAR.

4. The simulation method of claim 1, wherein the modeling step of generating four phase-shifted measurement light modulation signals for the measurement light includes a step of removing noise by multiplexing a demodulation signal of the measurement light into four phase shifts.

5. The simulation method of claim 1, wherein the modeling step of obtaining the cross-correlation between the detection light signal and the four phase-shifted measurement light modulation signals includes a step of obtaining a measurement light modulation signal phase-shifted by 0 degrees, a measurement light modulation signal phase-shifted by 90 degrees, a measurement light modulation signal phase-shifted by 180 degrees, and a measurement light modulation signal phase-shifted by 270 degrees for the detection light signal, performing a one-dimensional numerical integration of each of the measurement light modulation signals, and multiplying each component subjected to the one-dimensional numerical integration by a reciprocal of an integration time (T_int) to obtain the cross-correlation in each phase.

6. A multipath interference correction system for a coaxial scanning LIDAR, the multiple interface correction system comprising:
a scanner driving unit configured to drive a scanner included in a coaxial scanning LIDAR and obtain a position signal of the scanner;
a measurement light modulation signal input unit configured to obtain a demodulation signal of measurement light emitted from laser of the coaxial scanning LIDAR;
a detection light input unit configured to receive detection light mixed with reflection light and multiple interference light from an avalanche photodiode of the coaxial scanning LIDAR and output a detection light signal; and
a real-time processor for outputting a depth map based on the detection light signal, the demodulation signal of the measurement light, and the position signal of the scanner,
wherein the real-time processor includes
a depth map generation unit configured to generate a depth map based on the detection light based on the detection light signal, the demodulation signal of the measurement light, and the scanner position signal, and
trained extreme gradient boosting (XG Boost) configured to be trained to correct distortion caused by the multiple interference light in the depth map based on the detection light and output the depth map in which multipath interference is corrected.

7. The multiple interface correction system of claim 6, wherein the trained XG boost is trained to correct a depth map error due to multiple interference light by using an XG Boost regressor based on a mixed light data set simulated by the simulation method of the coaxial scanning LIDAR.

8. The multiple interface correction system of claim 7, wherein the X-Boost regressor determines an optimized hyperparameter using a Tree-structured Parzen Estimator (TPE)-based Bayesian optimization algorithm.

9. The multiple interface correction system of claim 7, wherein the simulation method of the coaxial scanning LIDAR includes
a step of modeling a detection light signal to which measurement light modulation, a reflection light model, and a multiple interference light model are applied,
a step of modeling a physical response of the avalanche photodiode,
a modeling step of generating four phase-shifted measurement light modulation signals for the measurement light, and
a modeling step of obtaining cross-correlation between the detection light signal and the four phase-shifted measurement light modulation signals.

10. The multiple interface correction system of claim 9, wherein the step of modeling the detection light signal to which the measurement light modulation, the reflection light model, and the multiple interference light model are applied includes
a step of modeling a reflection light signal based on the reflection light model, modeling a multiple interference light signal based on the multiple interference light model, deriving the number of photons of the detection light based on power and carrier travel time of the detection light signal, energy of a photon, and a laser wavelength, and determining the number of photons of the detection light by applying background light and photon shot noise.

11. The multiple interface correction system of claim 9, wherein the step of modeling a physical response of the avalanche photodiode includes a step of removing an influence of dark current, TIA noise, and thermal noise from a detection light signal received by the coaxial scanning LIDAR.

12. The multiple interface correction system of claim 9, wherein the modeling step of generating four phase-shifted measurement light modulation signals for the measurement light includes a step of removing noise by multiplexing a demodulation signal of the measurement light into four phase shifts.

13. The multiple interface correction system of claim 9, wherein the modeling step of obtaining the cross-correlation between the detection light signal and the four phase-shifted measurement light modulation signals includes the step of obtaining a measurement light modulation signal phase-shifted by 0 degrees, a measurement light modulation signal phase-shifted by 90 degrees, a measurement light modulation signal phase-shifted by 180 degrees, and a measurement light modulation signal phase-shifted by 270 degrees for the detection light signal, performing a one-dimensional numerical integration of each of the measurement light modulation signals, and multiplying each component subjected to the one-dimensional numerical integration by a reciprocal of an integration time (T_int) to obtain the cross-correlation in each phase.

14. A multipath interference correct method for a coaxial scanning LIDAR including a scanner driving unit configured to drive a scanner included in a coaxial scanning LIDAR and obtain a position signal of the scanner, a measurement light modulation signal input unit configured to obtain a demodulation signal of measurement light emitted from laser of the coaxial scanning LIDAR, a detection light input unit configured to receive detection light mixed with reflection light and multiple interference light from an avalanche photodiode of the coaxial scanning LIDAR and output a detection light signal, and a real-time processor for outputting a depth map based on the detection light signal, the demodulation signal of the measurement light, and the position signal of the scanner, the multipath interference correct method comprising:
a depth map generation step of generating, by the real-time processor, a depth map based on the detection light based on the detection light signal, the demodulation signal of the measurement light, and the scanner position signal, and
a step of outputting the depth map in which the multipath interference is corrected using trained extreme gradient boosting (XG Boost) trained to correct distortion caused by the multiple interference light in the depth map based on the detection light.

15. The multipath interference correct method of claim 14, wherein the trained XG boost is trained to correct a depth map error due to multiple interference light by using an XG Boost regressor based on a mixed light data set simulated by the simulation method of the coaxial scanning LIDAR.

16. The multipath interference correct method of claim 15, wherein the X-Boost regressor determines an optimized hyperparameter using a Tree-structured Parzen Estimator (TPE)-based Bayesian optimization algorithm.

17. The multipath interference correct method of claim 15, wherein the simulation method of the coaxial scanning LIDAR includes
a step of modeling a detection light signal to which, measurement light modulation, a reflection light model, and a multiple interference light model are applied,
a step of modeling a physical response of the avalanche photodiode,
a modeling step of generating four phase-shifted measurement light modulation signals for the measurement light, and
a modeling step of obtaining cross-correlation between the detection light signal and the four phase-shifted measurement light modulation signals.

18. The multipath interference correct method of claim 17, wherein the step of the detection light signal to which the measurement light modulation, the reflection light model, and the multiple interference light model are applied includes
a step of modeling a reflection light signal based on the reflection light model, modeling a multiple interference light signal based on the multiple interference light model, deriving the number of photons of the detection light based on power and carrier travel time of the detection light signal, energy of a photon, and a laser wavelength, and determining the number of photons of the detection light by applying background light and photon shot noise.

19. The multipath interference correct method of claim 17, wherein the step of modeling a physical response of the avalanche photodiode includes a step of removing an influence of dark current, TIA noise, and thermal noise from a detection light signal received by the coaxial scanning LIDAR.

20. The multipath interference correct method of claim 17, wherein the modeling step of generating four phase-shifted measurement light modulation signals for the measurement light includes a step of removing noise by multiplexing a demodulation signal of the measurement light into four phase shifts, and
the modeling step of obtaining the cross-correlation between the detection light signal and the four phase-shifted measurement light modulation signals includes the step of obtaining a measurement light modulation signal phase-shifted by 0 degrees, a measurement light modulation signal phase-shifted by 90 degrees, a measurement light modulation signal phase-shifted by 180 degrees, and a measurement light modulation signal phase-shifted by 270 degrees for the detection light signal, performing a one-dimensional numerical integration of each of the measurement light modulation signals, and multiplying each component subjected to the one-dimensional numerical integration by a reciprocal of an integration time (T_int) to obtain the cross-correlation in each phase.
